(19) United States
(12) Patent Application Publication
(10) Pub. No.: US 2006/0091556 A1
(43) Pub. Date: May 4, 2006

(54) Semiconductor device and its manufacturing method

(76) Inventor: Takashi Shigeoka, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/255,882

(22) Filed: Oct. 24, 2005

(30) Foreign Application Priority Data
Oct. 28, 2004 (JP) 2004-314328

(51) Int. Cl. H01L 23/48

(52) U.S. Cl. 257/773

(57) ABSTRACT

A semiconductor device with a new three-dimensional structure comprises a semiconductor substrate including a trench vertically formed to a surface of the semiconductor substrate, a plurality of isolations formed in side and bottom surfaces of the trench in a depth direction of the trench, a plurality of functional elements formed on the side surfaces of the trench separated be the isolation and including an insulator, an electrode formed on the insulator and a pair of source/drain formed in the both sides of the electrode in the depth direction, and a wiring connected to the electrodes located in both sides of the isolation.

### CROSS-REFERENCE TO RELATED APPLICATIONS

This application is based upon and claims the benefit of priority from prior Japanese Patent Application No. 2004-314328, filed Oct. 28, 2004, the entire contents of which are incorporated herein by reference.

### BACKGROUND OF THE INVENTION

1. Field of the Invention

The present invention relates to a semiconductor device and its manufacturing method, and more particularly to a highly integrated three-dimensional semiconductor device and its manufacturing method.

2. Description of the Related Art

For an integrated circuit, high integration has been achieved by miniaturizing elements which constitute the circuit. However, when miniaturization is further pursued, there is one physical limit, called as a fine-line effect. The fine-line effect is a phenomenon, for example, resistance of a metal increases exponentially if a size of the metal wiring becomes 20 nm or less. If a wiring width becomes 20 nm or less, the resistance is believed to increase because flow of electrons in the metal is disturbed due to colliding of electrons with a wall of the metal wiring, as a mean free path of electron in the metal is about 20 nm at a room temperature. Thus, there is a limit in a two-dimensional miniaturization.

An example of a three-dimensional device is disclosed in Jpn. Pat. Appln. KOKAI Publication No. 5-315622. The device is a nonvolatile memory in which, in an independent square trench, an electrode, an insulator and the like are concentrically arranged therein. This structure is not applicable to a semiconductor device with a feature size of 20 nm or less because it is hard to reduce a trench size to such an extent without causing the fine-line effect.

In addition, one example of technical problems of three-dimensional device manufacturing is a lateral etching or doping technology on a side surface of a trench to process, for example. Jpn. Pat. Appln. KOKAI Publication No. 2002-231966 discloses a lateral anisotropic etching technology. According to this technology, to reduce a variance in sensitivity of a semiconductor sensor, a cavity is formed to extend in a horizontal direction in a silicon substrate. This cavity is formed as follows. A material having positive fixed charges, such as ice or pn junction, is disposed on a bottom of a vertically formed groove. A track of reactive etching ions that enter vertically to the bottom is laterally bent in the vicinity of the fixed charges on the bottom, thus executing lateral etching. This method has a problem in controlling a lateral etching amount by stabilizing the amount of fixed charges applied to the bottom.

Therefore, there is a demand for a new three-dimensional device structure, e.g., a structure in which a plurality of semiconductor elements are formed on a side face of a trench or the like, and a development of its manufacturing technology.

### BRIEF SUMMARY OF THE INVENTION

According to one aspect of the present invention, it is provided a semiconductor device comprising: a semiconductor substrate including a trench vertically formed to a surface of the semiconductor substrate; a plurality of isolations formed in side and bottom surfaces of the trench in a depth direction of the trench; a plurality of functional elements formed on the side surfaces of the trench separated be the isolation and including an insulator, an electrode formed on the insulator and a pair of source/drain formed in the both sides of the electrode in the depth direction; and a wiring connected to the electrodes located in both sides of the isolation.

According to another aspect of the present invention, it is provided a semiconductor device comprising: a semiconductor substrate including a trench vertically formed to a surface of the semiconductor substrate; a plurality of isolations formed in an inner face of the trench in a vertical direction to the surface of the semiconductor substrate so as to separate the inner surface, separated inner surfaces separated by the isolations including an inner side surface and an inner bottom surface, respectively; a plurality of memory elements formed on the inner side surface, including at least two gate insulators formed in the vertical direction, a plurality of source/drain formed in both sides of each gate insulator in the vertical direction and floating gate electrodes formed on the gate insulators and interelectrode insulators formed on the floating gate electrodes; and at least two control gates electrode connecting the floating gate electrodes which adjoined in the both sides of the isolation.

According to still another aspect of the present invention, it is provided a method of manufacturing a semiconductor device, comprising: forming a first trench in a semiconductor layer vertically to a surface of the semiconductor layer; forming a first insulator on an inner surface of the first trench; forming a first silicon film on the first insulator; forming isolations in the first insulator, the first silicon film, and the semiconductor layer in side and bottom faces of the first trench in a depth direction thereof; forming a second insulator on surfaces of the first silicon film and the isolation; forming a second silicon film on the second insulator; removing the first and second insulators and the first and second silicon films formed on a bottom of the first trench; forming an alternate stacked film of third and fourth insulators in the first trench to be parallel to the bottom face thereof; forming a second trench in a center of the alternate stacked film; forming an electrode in a bottom face of the second trench; removing the third insulator; patterning the second silicon film, the second insulator, the first silicon film, and the first insulator by using the fourth insulator as a mask while applying a potential to the electrode; and introducing conductive impurities into the semiconductor layer while applying the potential to the electrode.

### BRIEF DESCRIPTION OF THE SEVERAL VIEWS OF THE DRAWING

FIGS. 1A to 1C are diagrams showing an example of a three-dimensional semiconductor device simplified to explain a concept of the present invention: FIG. 1A is a plan layout diagram, FIG. 1B is a sectional view of an MOS transistor formed on a side face of a trench cut along a cutting line 1B-1B of FIG. 1A, and FIG. 1C is a sectional view cut long a cutting line 1C-1C of FIG. 1A;

FIG. 2 is a perspective diagram showing an example of a three-dimensional semiconductor memory device according to a first embodiment of the present invention;

FIGS. 3A, 3B are diagrams showing an example of a manufacturing process of a three-dimensional NAND type semiconductor memory device according to the first embodiment of the present invention: FIG. 3A is a sectional view of a trench vertical to a longitudinal direction, and FIG. 3B is a sectional view parallel to a silicon substrate surface cut near a center of a trench depth shown along a cutting line 3B-3B of FIG. 3A;

FIGS. 4A, 4B are diagrams showing an example of the manufacturing process of the semiconductor memory device of the first embodiment sequent to that of FIGS. 3A, 3B: FIG. 4A is a sectional view of a trench vertical to a longitudinal direction, and FIG. 4B is a sectional view parallel to the silicon substrate surface cut near a center of a trench depth shown along a cutting line 4B-4B of FIG. 4A;

FIGS. 5A to 5C are diagrams showing an example of the manufacturing process of the semiconductor memory device of the first embodiment sequent to that of FIGS. 4A, 4B: FIG. 5A is a sectional view of a trench vertical to a longitudinal direction, FIG. 5B is a sectional view parallel to the silicon substrate surface cut near a center of a trench depth along the cutting line 5B-5B of FIG. 5A, and FIG. 5C is a sectional view of a side face of the trench in the longitudinal direction along a cutting line 5C-5C of FIG. 5A;

FIGS. 6A, 6B are diagrams showing an example of the manufacturing process of the semiconductor memory device of the first embodiment sequent to that of FIGS. 5A to 5C: FIG. 6A is a sectional view of a trench vertical to a longitudinal direction, and FIG. 6B is a sectional view parallel to the silicon substrate surface cut near a center of a trench depth shown along a cutting line 6B-6B of FIG. 6A;

FIGS. 7A, 7B are diagrams showing an example of the manufacturing process of the semiconductor memory device of the first embodiment sequent to that of FIGS. 6A, 6B: FIG. 7A is a sectional view of a trench vertical to a longitudinal direction, and FIG. 7B is a sectional view parallel to the silicon substrate surface cut near a center of a trench depth shown along a cutting line 7B-7B of FIG. 7A;

FIGS. 8A to 8C are diagrams showing an example of the manufacturing process of the semiconductor memory device of the first embodiment sequent to that of FIGS. 7A, 7B: FIG. 8A is a sectional view of a trench vertical to a longitudinal direction, FIG. 8B is a sectional view parallel to the silicon substrate surface cut near a center of a trench depth along the cutting line 8B-8B of FIG. 8A, and FIG. 8C is a sectional view of a side face of the trench in the longitudinal direction along a cutting line 8C-8C of FIG. 8A;

FIGS. 9A to 9C are diagrams showing an example of the manufacturing process of the semiconductor memory device of the first embodiment sequent to that of FIGS. 8A to 8C: FIG. 9A is a sectional view of a trench vertical to a longitudinal direction, FIG. 9B is a sectional view parallel to the silicon substrate surface cut near a center of a trench depth along the cutting line 9B-9B of FIG. 9A, and FIG. 9C is a sectional view of a side face of the trench in the longitudinal direction along a cutting line 9C-9C of FIG. 9A;

FIGS. 10 is a diagram showing an example of the manufacturing process of the semiconductor memory device of the first embodiment sequent to that of FIGS. 9A to 9C showing a sectional view of a trench vertical to a longitudinal direction;

FIGS. 11A, 11B are diagrams showing an example of the manufacturing process of the semiconductor memory device of the first embodiment sequent to that of FIG. 10: FIG. 11A is a sectional view of a trench vertical to a longitudinal direction, and FIG. 11B is a sectional view parallel to the silicon substrate surface cut near a center of a trench depth shown along a cutting line 11B-11B of FIG. 11A;

FIGS. 12A, 12B are diagrams showing an example of a manufacturing process according to a second embodiment of the present invention; FIG. 12A is a sectional view of a trench vertical to a longitudinal direction, and FIG. 12B is a sectional view of a trench end in the longitudinal direction;

FIGS. 13A, 13B are diagrams showing an example of the manufacturing process of the second embodiment sequent to that of FIGS. 12A, 12B: FIG. 13A is a sectional view of a trench vertical to a longitudinal direction, and FIG. 13B is a sectional view of a trench end in the longitudinal direction;

FIGS. 14A, 14B are diagrams showing an example of the manufacturing process of the second embodiment sequent to that of FIGS. 13A, 13B: FIG. 14A is a sectional view of a trench vertical to a longitudinal direction, and FIG. 14B is a sectional view of a trench end in the longitudinal direction;

FIGS. 15A, 15B are diagrams showing an example of the manufacturing process of the second embodiment sequent to that of FIGS. 14A, 14B: FIG. 15A is a sectional view of a trench vertical to a longitudinal direction, and FIG. 15B is a sectional view of a trench end in the longitudinal direction;

FIG. 16 is a diagram showing an example of an RIE device used for implementing the second embodiment;

FIGS. 17A to 17C are sectional views showing a processing example of a semiconductor substrate according to the second embodiment;

FIG. 18 is a sectional view showing an example of a wiring contact of a three-dimensional semiconductor memory device according to a third embodiment of the present invention; and

FIGS. 19A to 19E are sectional views showing an example of a manufacturing process of the wiring contact of the three-dimensional semiconductor memory device according to the third embodiment of the present invention.

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

The present invention relates to a semiconductor device with a three-dimensional structure in which high integration is realized by forming, e.g., a plurality of semiconductor functional elements such as a metal oxide semiconductor (MOS) transistor and a storage element on a side face of a groove such as a trench formed in a semiconductor surface layer, and its manufacturing method. For the semiconductor layer, not only a semiconductor substrate such as a silicon substrate but also a semiconductor layer (including single crystal layer, polycrystal layer or amorphous layer) formed on the semiconductor substrate or a silicon-on-insulator (SOI), or the like can be used.

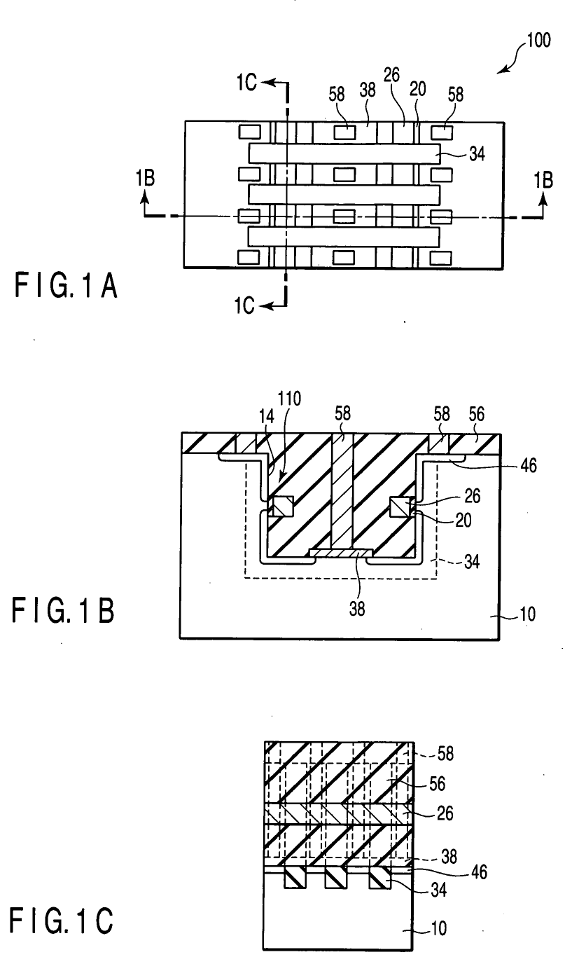

A essential concept of the present invention will be described by taking an example of FIGS. 1A to 1C. FIGS. 1A to 1C shows a most simplified form of a three-dimensional semiconductor device 100 according to the present invention. The three-dimensional semiconductor device 100 comprises only one row of MOS transistors 110 formed in a depth direction of a trench 14 in both side of long side faces of the trench 14 extending laterally formed in a semiconductor substrate 10. FIG. 1A is a plan layout diagram, FIG. 1B is a sectional view of the MOS transistor 110 formed on the side face of the trench 14 cut along a cutting line 1B-1B of FIG. 1A, and FIG. 1C is a sectional view cut along a line 1C-1C of FIG. 1A.

The MOS transistor 110 includes a gate insulator 20 formed on the side face of the trench 14, a gate electrode 26, and a source/drain 46 formed in the semiconductor substrate 10. The plurality of MOS transistors 110 are formed on the long side face of the trench 14, and isolated by isolations 34. The isolation 34 is formed in the depth direction of the trench 14 in the semiconductor substrate 10 in side and bottom faces of the trench 14. The gate electrode 26 connects the MOS transistor 110 in a first direction which is a longitudinal direction of the trench 14 to serve as a word line. The source/drain 46 is connected to a bit line (not shown) via a contact 58. A bottom electrode 38 is formed on the bottom face of the trench 14, the inside of the trench 14 is filled with a burying insulator 56, and a surface of the semiconductor substrate 110 is covered with a part of the burying insulator 56.

The three-dimensional semiconductor device 100 can be formed by arranging plural rows of such MOS transistors 110 in the depth direction on the side face of the trench 14. According to the present invention, even if the functional elements formed on the surface of the semiconductor substrate 10 are miniaturized, feature size restrictions in the depth direction in the trench are not severe, but each component can be formed to a desired size. Thus, in the case of realizing high integration, it can be solved the problems in the miniaturization of the conventional planar two-dimensional semiconductor device, i.e., reduction in performance caused by the fine-line effect.

Some embodiments of the present invention will be described in detail below with reference to the accompanying drawings.

### First Embodiment

A first embodiment of the present invention is directed to a three-dimensional semiconductor memory device in which a plurality of thin and long trenches are formed in a semiconductor substrate, and two-dimensionally arranged functional elements such as NAND type memory cells are formed on side faces of both sides.

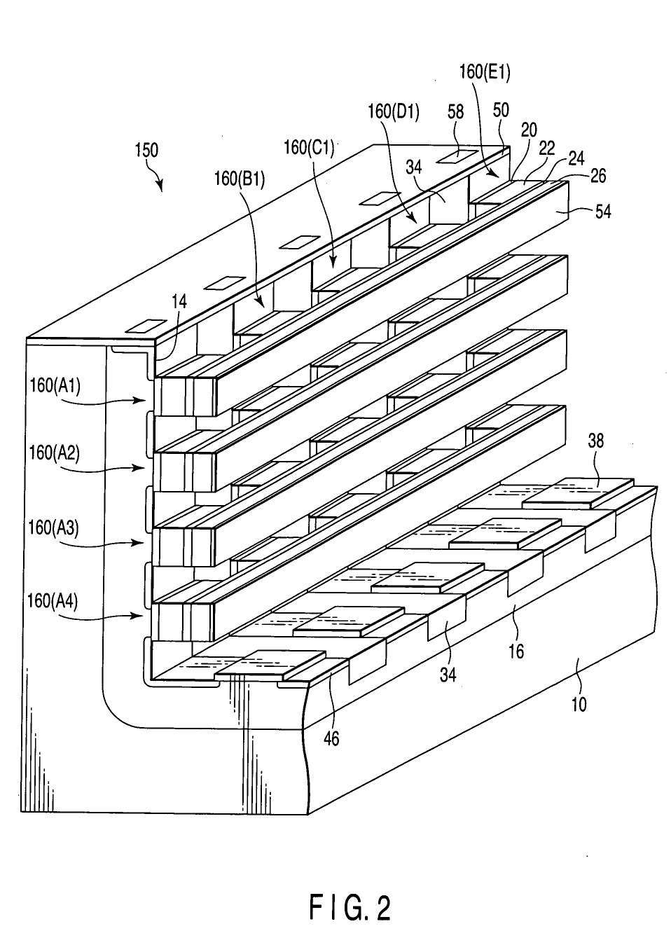

FIG. 2 is a perspective diagram illustrating a three-dimensional semiconductor memory device 150 according to the embodiment. The embodiment is a NAND type memory cell array 150 formed by arranging two-dimensional memory cells 160 on a side face of a trench 14. In the drawing, parts are omitted to help to understand a structure of the three-dimensional semiconductor memory device 150. Each memory cell 160 includes a gate insulator 20, a floating gate electrode (FG) 22, an interelectrode insulator 24, and a control gate electrode (CG) 26. The FG's 22 of the memory cells 160 such as memory cells 160(A1) to 160(E1) formed in a horizontal direction of the trench 14 are isolated by isolations 34 formed in a semiconductor substrate 10, e.g., a silicon substrate, and connected in a first direction which is the longitudinal direction (direction parallel to a surface of the semiconductor substrate 10) of the trench 14 by the CG 26. The CG 26 on which a silicide layer 54 is formed serves as a word line. A plurality (four in the drawing) of memory cells 160 such as the memory cells 160(A1) to 160(A4) formed in the depth direction on the side face of the trench 14 are serially and electrically connected in a second direction which is the depth direction of the trench 14 by the source/drain 46 formed in the semiconductor substrate 10 on the side face of the trench 14, and connected to a bit line (not shown) via a bit line contact 58. Thus, the three-dimensional semiconductor memory device can be formed by arranging the memory cells 160 on the side face of the trench 14.

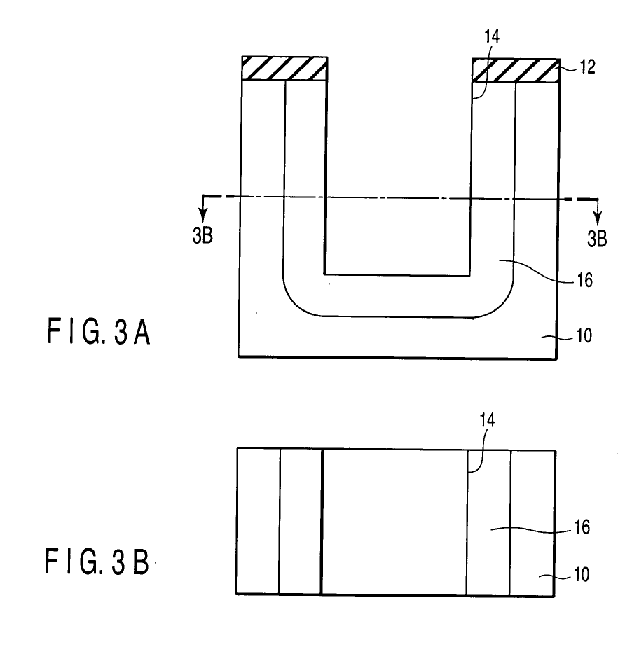

A manufacturing process of the NAND type memory cell array 150 of the embodiment will be described below with reference to FIGS. 3A, 3B to FIGS. 11A, 11B. The embodiment will be described by taking an example of an n channel NAND type memory cell array 150. However, a p channel type memory cell array can be similarly manufactured.

(1) First, as shown in FIGS. 3A, 3B, a trench 14 and a well 16 are being formed in a semiconductor substrate 10, e.g., a silicon substrate. FIG. 3A is a sectional view of the trench 14 vertical to a longitudinal direction, and FIG. 3B is a sectional view parallel to a surface of the silicon substrate 10 cut near a center of a depth of the trench 14 along the cutting line 3B-3B of FIG. 3A.

A first insulator (mask insulator) 12 is formed on the silicon substrate 10. The first insulator 12 is used as a mask when the trench 14 is formed. For example, a silicon oxide film (SiO₂ film) or a silicon nitride film (SiN film) formed by thermal oxidation or chemical vapor deposition (CVD) can be used. A pattern of the thin and long trench 14 is formed in the first mask insulator 12 by lithography and etching. By using the first insulator 12 as a mask, a deep trench 14 for forming memory cells 160 is formed in the silicon substrate 10 by, e.g., reactive ion etching (RIE). A side face of the longitudinal direction of the trench 14 is preferably (100) plane or a surface close to that. It is because the (100) plane is suitable to forming a MOS transistor thereon as its surface state density is less than those of other crystal planes.

Subsequently, p type dopant, e.g., boron (B), is implanted to side and bottom faces of the trench 14 at high energy from an oblique direction, and then annealing is executed to form a well 16.

Thus, as shown in FIGS. 3A, 3B, the trench 14 and the well 16 can be formed in the silicon substrate 10.

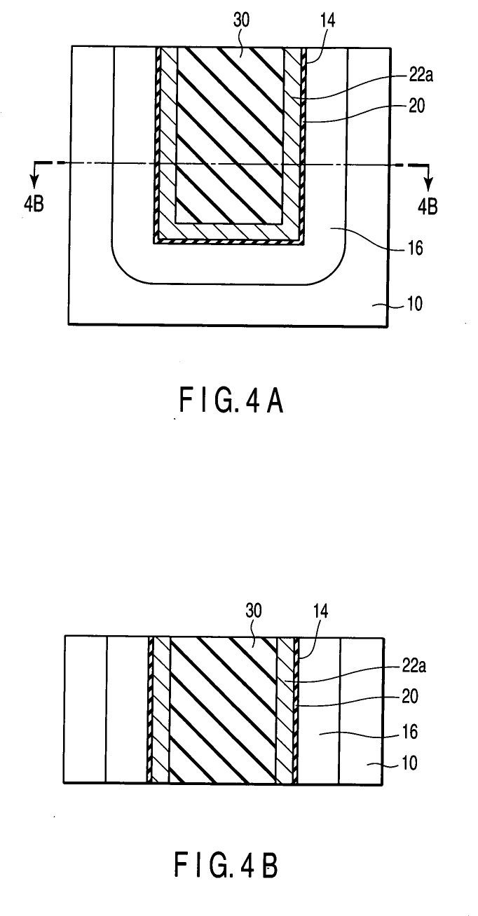

(2) Next, as shown in FIGS. 4A, 4B, a gate insulator 20 and a first polycrystalline silicon (polysilicon) film 22a for an FG 22 are being formed in the trench 14. FIG. 4A is a sectional view of the trench 14 vertical to the longitudinal direction, and FIG. 4B is a sectional view parallel to a surface of the silicon substrate 10 cut near the depth center of the trench 14 along the cutting line 4B-4B of FIG. 4A.

First, a gate insulator 20 is formed on an entire surface including an inner surface of the trench 14. For the gate insulator, for example, SiO₂ film formed by thermal oxidation, a silicon oxynitride film (SiON film) formed by oxidizing an SiN film, or a high dielectric constant insulator such as a hafnium silicate film (HfSiO film) or a hafnium silicon oxynitride film (HfSiON film) having a dielectric constant higher than that of SiO₂ film, can be used. The gate insulator 20 can be preferably formed by thermal oxidation, CVD or atomic layer deposition (ALD) which is able to form an uniform film on the side face of the trench 14.

Subsequently, a first polysilicon film 22a is deposited over an entire surface of the gate insulator 20. The first polysilicon film 22a is patterned into an FG 22 in a subsequent step. For the first polysilicon film 22a, a polysilicon film containing a high concentration of n type dopant, e.g., phosphorus (P) or arsenic (As), can be used. The film can be formed by, for example, CVD which is capable of depositing uniformly on both side and bottom faces of the trench 14.

Then, the gate insulator 20 and the first polysilicon film 22a formed on the front surface of the silicon substrate 10 are removed by, e.g., chemical mechanical polishing (CMP), to expose the surface of the silicon substrate 10. Subsequently, a second insulator (burying insulator) 30 is deposited thick to fill the trench 14 therewith. The second burying insulator 30 deposited on the surface of the silicon substrate 30 is simultaneously removed and planarized by, e.g., CMP.

Thus, as shown in FIGS. 4A, 4B, the first polysilicon film 22a and the gate insulator 20 to form the FG 22 can be formed in the trench 14.

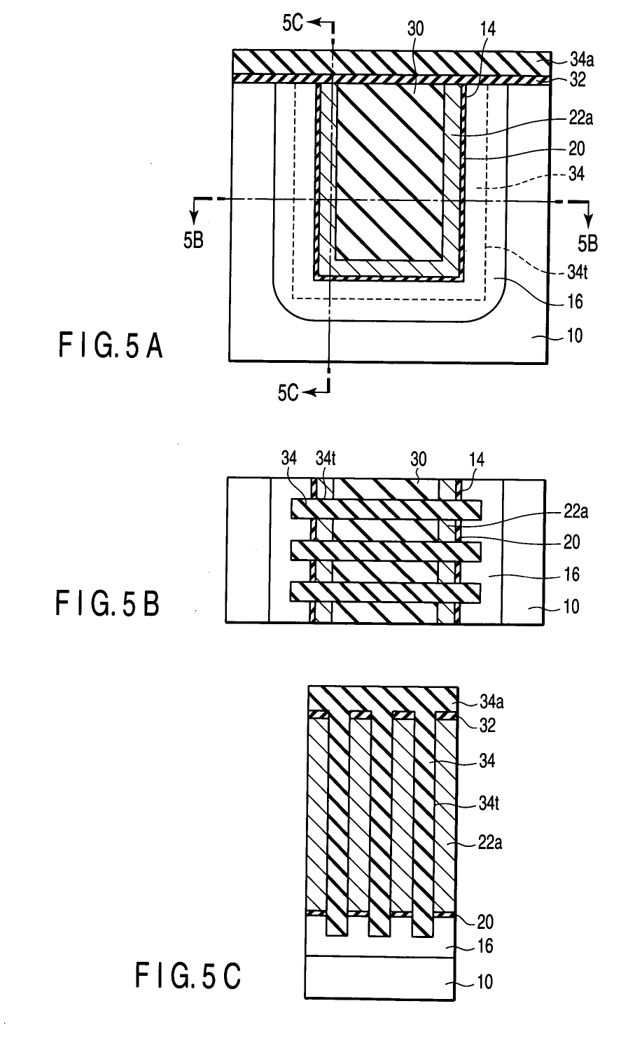

(3) Next, as shown in FIGS. 5A to 5C, isolation 34 is being formed in the side and bottom faces of the trench 14. FIG. 5A is a sectional view of the trench 14 vertical to the longitudinal direction, FIG. 5B is a sectional view parallel to the surface of the silicon substrate cut near the depth center of the trench 14 along the cutting line 5B-5B of FIG. 5A, and FIG. 5C is a sectional view of a side face of the longitudinal direction of the trench 14 along the cutting line 5C-5C of FIG. 5A.

Here, a third insulator (mask insulator) 32, e.g., SiN film, is formed over an entire surface. In the third insulator 32, a pattern to form an isolation such as a shallow trench isolation (STI) 34 is formed by lithography and etching. As can be seen in FIGS. 5A, 5B, the pattern of the STI 34 is formed to connect the silicon substrates 10 of both sides across the trench 14.

By using the third insulator 32 as a mask, the side face of the trench 14 of the silicon substrate 10, the gate insulator 20, the first polysilicon film 22a, and the second insulator 30 are simultaneously etched to the bottom face of the trench 14 by RIE. Further, the silicon substrate 10 at the bottom of the trench 14 is etched to form STI trench 34t in the side and bottom faces of the trench 14. As a result, the gate insulator 20 and the first polysilicon film 22a are separated in the longitudinal direction of the trench 14 by the STI trench 34t. Then, a fourth insulator (isolation insulator) 34a is deposited over an entire surface to fill the STI trench 34t. For the fourth insulator 34a, e.g., CVD-SiO₂ film can be used.

Thus, the STI 34 can be formed in which the inside of the STI trench 34t is filled with the fourth isolation insulator 34a shown in FIGS. 5A to 5C.

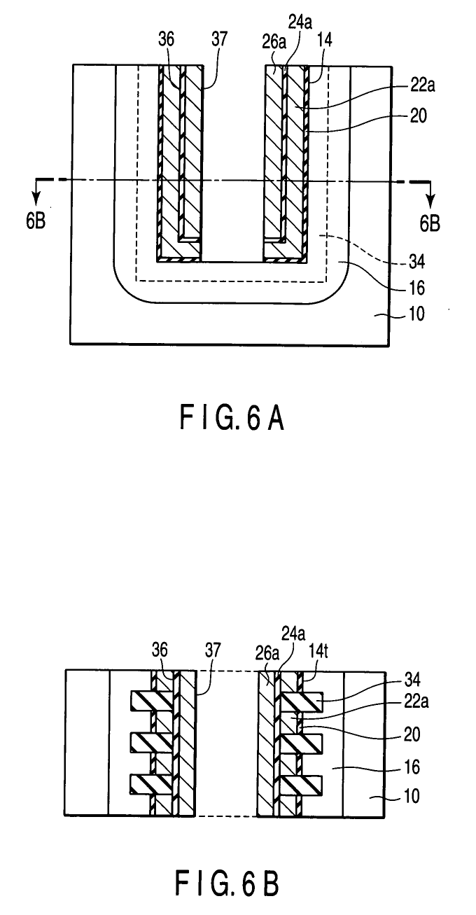

(4) Next, as shown in FIGS. 6A, 6B, an interelectrode insulator 24 and a second polysilicon film 26a for a CG 26 are being formed on the first polysilicon film 22a. FIG. 6A is a sectional view of the trench 14 vertical to the longitudinal direction, and FIG. 6B is a sectional view parallel to the surface of the silicon substrate 10 cut near the depth center of the trench 14 along the cutting line 6B-6B of FIG. 6A.

Here, the fourth isolation insulator 34a on the silicon substrate 10 is removed by, e.g., CMP, and the third mask insulator 32 is removed and planarized the surface.

Then, a second trench 36 is formed in the second burying insulator 30 and isolation insulator 34 in the center of the trench 14 by a similar process as that of the trench 14. The second trench 36 is formed to expose the surface of the first polysilicon film 22a formed on the side face of the trench 14, and the surfaces of the first polysilicon film 22a and the isolation insulator 34a on the bottom face of the trench 14.

Next, an interelectrode insulator material film 24a is deposited over an entire surface including the first polysilicon film 22a in the second trench 36 by a method having a high coverage of a side face of the trench 36, e.g., CVD, ALD. As the interelectrode insulator 24a, for example, SiO₂, SiN, SiON, or aluminum oxide (Al₂O₃) can be used. Moreover, a second polysilicon film 26a is deposited over an entire surface on the interelectrode insulator material film 24a. For example, the second polysilicon film 26a is a CVD-silicon film doped with a high concentration of n type impurities such as phosphorus (P) or arsenic (As) as in the case of the first polysilicon film 22a.

Then, to expose the silicon substrate 10 at a bottom of a newly formed third trench 37 surrounded by the second polysilicon film 26a, the second polysilicon film 26a, the interelectrode 24, the first polysilicon film 22a and the gate insulator 20 in the bottom of the third trench 37 are removed by, e.g. RIE. At that time, the isolation insulator 34a in the bottom of the third trench 37 is partly removed by, e.g., RIE, to make flat a bottom face of the third trench 37.

Subsequently, the second polysilicon film 26a and the interelectrode insulator material film 24adeposited on the surface of the silicon substrate 10 are removed by, e.g., CMP, to expose the surface of the silicon substrate 10.

Accordingly, as shown in FIGS. 6A, 6B, the interelectrode insulating material film 24a and the second polysilicon film 26a are deposited on the first polysilicon film 22a in the second trench 36, thus forming the third trench 37.

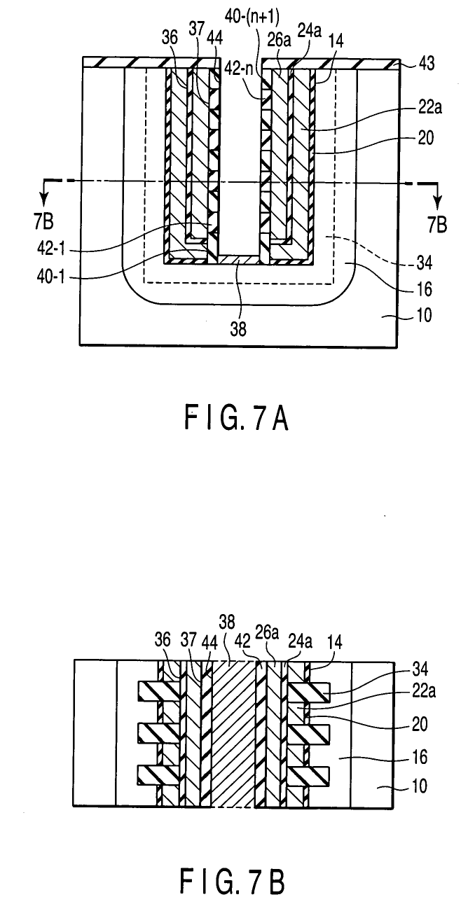

(5) Next, a preprocess for forming a plurality of memory cells 160 on the side face of the trench 14 is being performed. As shown in FIGS. 7A, 7B, a stacked film of two kinds of insulators 40, 42 having different etching characteristics and a trench bottom electrode 38 for horizontal (lateral) processing are being formed in the third trench 37. FIG. 7A is a sectional view of the trench 14 vertical to the longitudinal direction, and FIG. 7B is a sectional view parallel to the surface of the silicon substrate 10 near the depth center of the trench 14 along the cutting line 7B-7B of FIG. 7A.

Here, by a method of selective deposition only on a horizontal plane parallel to the surface of the silicon substrate 10, two kinds of insulators having different etching characteristics are alternately deposited to be parallel to the bottom face of the third trench 37. As methods of selective deposition in the horizontal direction, there are, for example, a long throw sputtering, a collimated sputtering, an ionized sputtering, and the like. The long throw sputtering is carried out by making a distance large between a target and the silicon substrate 10. The collimated sputtering is equipped with a collimator for separating and depositing a vertical component alone to the silicon substrate 10. The ionized sputtering is a method for ionizing a material to be deposited, and depositing it by applying a bias to the silicon substrate 10. First, a fifth insulator 40-1, e.g., an SiO₂ film, is deposited. The fifth insulator 40 has characteristics to be easily etched. Next, a sixth insulator (mask insulator) 42-1, e.g., SiN film, is deposited on the fifth insulator 40-1. The sixth insulator 42 is more difficult to be etched than the fifth insulator 40-1. Accordingly, deposition of the fifth and sixth insulators 40 and 42 is repeated by n times, and a fifth insulator 40-(n+1) is lastly deposited to fill the third trench 37 with the alternate stacked film of the fifth and sixth insulators 40 and 42. In this case, a thickness of the fifth insulator 40 becomes equal to a space between the CG electrodes, and a thickness of the sixth mask insulator 42 becomes equal to a width of the CG. Since the thickness of the sixth insulator 42 can be set independently of feature size of the functional elements formed on the surface of the silicon substrate 10, the CG width can be increased to a width to prevent an occurrence of the fine-line effect. For the fifth and sixth insulators 40 and 42, a combination is not limited to that of the SiO₂ film and the SiN film as long as films are different in etching characteristics.

The stacked film of the fifth and sixth insulators 40 and 42 deposited on the silicon substrate 10 except for that in the third trench 37 is removed by, e.g., CMP, to planarize the surface. Then, a seventh insulator (protective insulator) 43 is formed as a protective film on the silicon substrate 10. The seventh insulator is preferably the same film as that of the sixth insulator 42, e.g., SiN film.

Subsequently, as shown in FIG. 7A, a fourth trench 44 is formed in a center of the stacked film formed in the third trench 37. Then, a bottom electrode 38 is formed on a bottom face of the fourth trench 44 by a deposition method only in a horizontal direction. Before the bottom electrode 38 is formed, a very thin insulator (not shown) is formed on the bottom of the trench 14 to insulate the bottom electrode 38 and the silicon substrate 10. A method of forming the bottom electrode 38 will be described later in detail (in second embodiment). As a material for the bottom electrode 38, a metal forming a silicide with silicon, e.g., titanium (Ti), polysilicon doped with a high concentration of n type impurities, or the like can be used. If a silicide forming metal is used, annealing is executed to silicidation, as described later. The very thin insulator formed to insulate the bottom electrode 38 is set to a thickness not to interfere with the silicidation.

Thus, a structure shown in FIGS. 7A, 7B can be made in which the two kinds of insulators 40, 42 having different etching characteristics one another and the trench bottom electrode 38 are formed in the third trench 37.

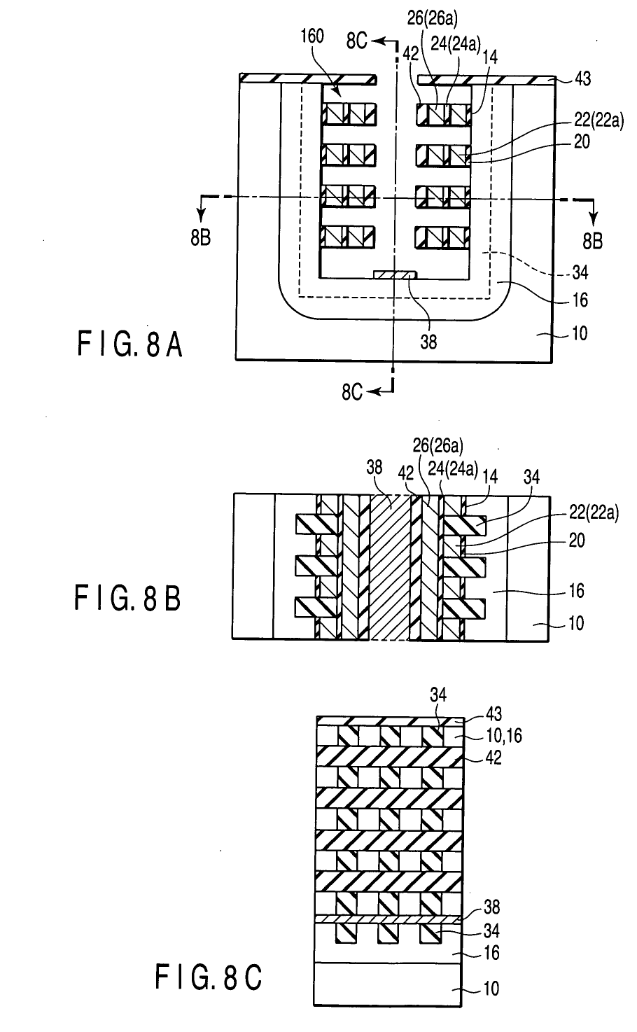

(6) Next, as shown in FIGS. 8A to 8C, films including the second polysilicon film 26a and the first polysilicon film 22a are being processed vertically to the side face of the trench 14, i.e., in a lateral direction parallel to the substrate surface, to form memory cells 160 isolated in the horizontal direction on the side face of the trench 14. FIG. 8A is a sectional view of the trench 14 vertical to the longitudinal direction, FIG. 8B is a sectional view parallel to the surface of the silicon substrate 10 cut near the depth center of the trench 14 along the cutting line 8B-8B of FIG. 8A, and FIG. 8C is a sectional view of the longitudinal side face of the trench 14 including a section cut along the line 8C-8C of FIG. 8A seen from a lateral direction.

First, of the stacked insulators 40, 42 formed in the center of the trench 14 in the previous step (5), the fifth insulator 40, e.g., SiO₂ film, etched easily is removed by buffered hydrofluoric acid (BHF).

Then, by using the remaining sixth insulator 42, e.g., SiN film, as a mask, the second polysilicon film 26a, the interelectrode insulator 24a, the first polysilicon film 22a, and the gate insulator 20 formed on the side face of the trench 14 are etched in a lateral direction to form a memory cell 160. The lateral etching can be executed by wet etching or RIE.

In the case of the wet etching, the polysilicon films 22a, 26a can be removed by a solution containing a nitric acid and a hydrofluoric acid. The insulators 24a, 20 containing SiO₂ can be removed by a solution containing a hydrofluoric acid. However, side etching may cause the memory cell 160 to be smaller in size than a size of the mask.

In the case of RIE, as described later in detail, a halogen based etching gas is ionized to be positive, and a positive potential is applied to the bottom electrode 38 and a negative potential is applied to the silicon substrate 10, respectively, to execute the etching processing. The positive etching ions are repelled by the positive electric field around the bottom electrode 38, and are attracted to the negative substrate potential to change a direction in a horizontal (lateral) direction, thereby etching the second polysilicon film 26a or the like from the lateral direction. As a result, the second polysilicon film 26a becomes a CG 26 which is isolated in the depth direction of the trench 14 to extend in the horizontal direction. The CG 26 connects memory cells formed at the same depth in the trench extending in the horizontal direction. In a portion from which the second polysilicon film 26a, the interelectrode insulator 24, the first polysilicon film 22a and the gate oxide 20 are removed, the silicon substrate 10 (well 16) is exposed.

Accordingly, as shown in FIGS. 8A to 8C, the memory cells 160 isolated in the depth direction of the trench 14 to be two-dimensionally arranged are formed on the side face of the trench 14.

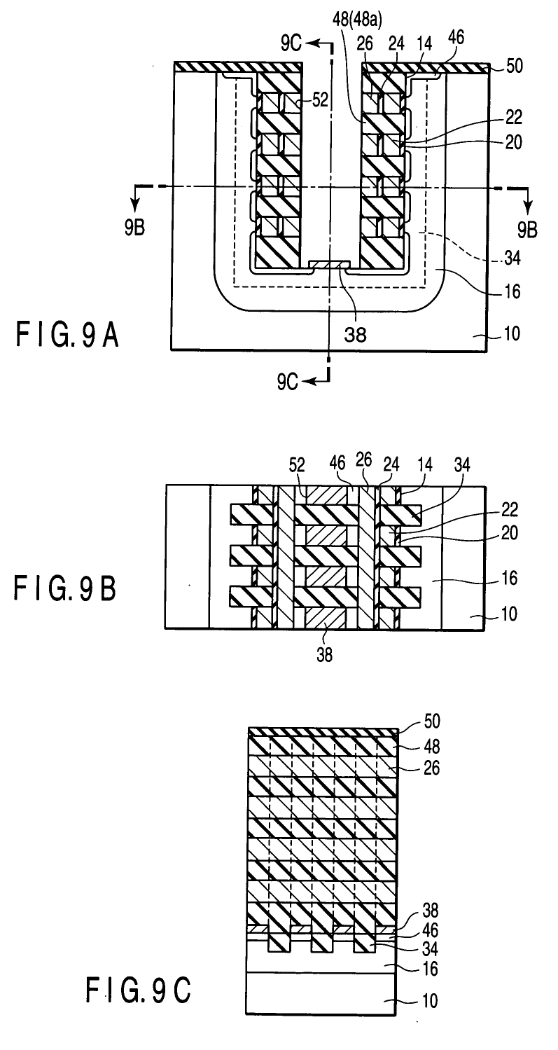

(7) Next, as shown in FIGS. 9A to 9C, a source/drain 46 is being formed, and an interlayer insulator 48 is being formed between the memory cells 160. FIG. 9A is a sectional view of the trench 14 vertical to the longitudinal direction, FIG. 9B is a sectional view parallel to the surface of the silicon substrate 10 cut near the depth center of the trench 14 along the cutting line 9B-9B of FIG. 9A, and FIG. 9C is a sectional view of the longitudinal side face of the trench 14 along the cutting line 9C-9C of FIG. 9A.

The silicon substrate 10 exposed in the trench 14, in the previous step (6), is doped with n type impurities such as As to form a source/drain 46. Before the doping with As, the seventh protective insulator 43 is removed in a surface area of the silicon substrate 10 where the source/drain 46 is being formed. For example, the doping with As can be executed by thermal diffusion of heating to a high temperature in a gas atmosphere containing As, or ion doping. As described later in detail, the ion doping is executed by ionizing As to be positive and applying a positive potential to the bottom electrode 38 and a negative potential to the silicon substrate 10.

Subsequently, annealing is carried out for a silicidation of the bottom electrode 38, when necessary. The bottom electrode 38 is silicided in a portion where the silicide forming metal is directly contacting with the silicon substrate 10, i.e., only on the bottom silicon face of the fourth trench 44, by reacting Ti with silicon, for example.

No silicide is formed on the STI 34 at the bottom SiO₂ face of the trench 44 since the isolation insulator 34 such as SiO₂ film does not react with the silicide forming metal. During the silicidation annealing, the very thin insulator (not shown) formed to insulate the bottom electrode 38 and the silicon substrate 10 is decomposed to disappear.

Then, the sixth and seventh insulators 42 and 43 used as masks, e.g., SiN films, are removed by a hot phosphoric acid. Further, a part or all of the un-silicided bottom electrode 38 are removed. When the bottom electrode 38 is silicided as described above, the unreacted bottom electrode 38 on the STI 34 can be removed, and thus the bottom electrode 38 can be separated in a self-aligned manner on the STI 34 portion.

Subsequently, an eighth insulator (interlayer insulator) 48a is formed over an entire surface to fill the trench between the gate electrodes. For the eighth insulator 48a, for example, SiO₂ film deposited by CVD can be used. Then, the eighth insulator 48a deposited on the surface of the silicon substrate 10 is removed by, e.g., CMP. To protect the surface of the silicon substrate 10, a ninth insulator 50, e.g., SiO₂ film, is formed on an entire surface.

Further, a fifth trench 52 is formed in the eighth insulator 48a in the trench 14 by lithography and etching. The fifth trench 52 is formed to expose a surface of the control gate 26. Accordingly, the eighth insulator 48a becomes an interlayer insulator 48 to isolate the memory cells 160 in the horizontal direction.

Thus, as shown in FIGS. 9A to 9C, the source/drain 46 and the interlayer insulator 48 can be formed.

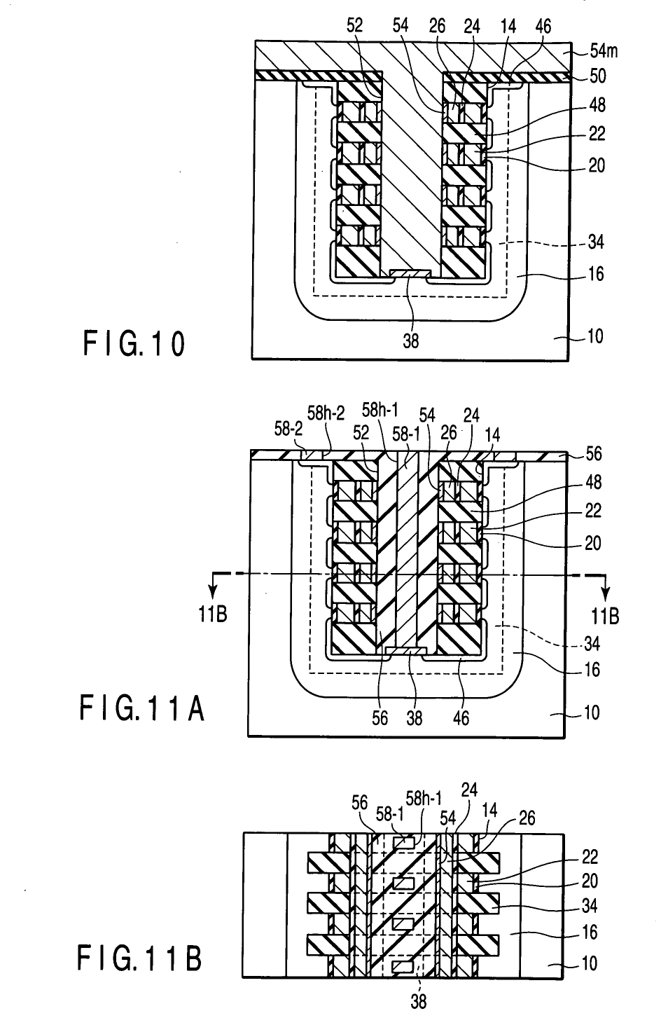

(8) Next, a silicide 54 is being formed on the surface of the CG 26. FIG. 10 is a sectional view of the trench 14 vertical to the longitudinal direction.

A silicide metal 54m is deposited over an entire surface including the inside of the trench 52 by a method having good coverage in the trench, e.g., the long throw sputtering, to fill the fifth trench 52 as shown in FIG. 10. For the silicide metal 54m, a metal having characteristic of forming silicide by high-temperature annealing and being removed an unreacted metal by wet processing is preferred. For example, cobalt (Co) or nickel (Ni) can be used. After the deposition of the silicide metal 54m, high-temperature annealing is executed to form a silicide 54 on the surface of the CG 26 contacted with the silicide metal 54m as shown in FIG. 10. As a result, the CG 26 becomes a so-called polycide structure in which the silicide 54 is formed on polysilicon.

In the silicidation process, a part of the ninth insulator 50 on the source/drain 46 on the surface of the silicon substrate 10 is removed before the silicide metal 54m is deposited, and both surfaces of the CG 26 and the source/drain 46 are simultaneously silicided, whereby a so-called salicide can be formed.

Subsequently, the unreacted silicide metal 54m is removed by wet processing, e.g., a mixed solution of a sulfuric acid (H₂SO₄) and a hydrogen peroxide (H₂O₂).

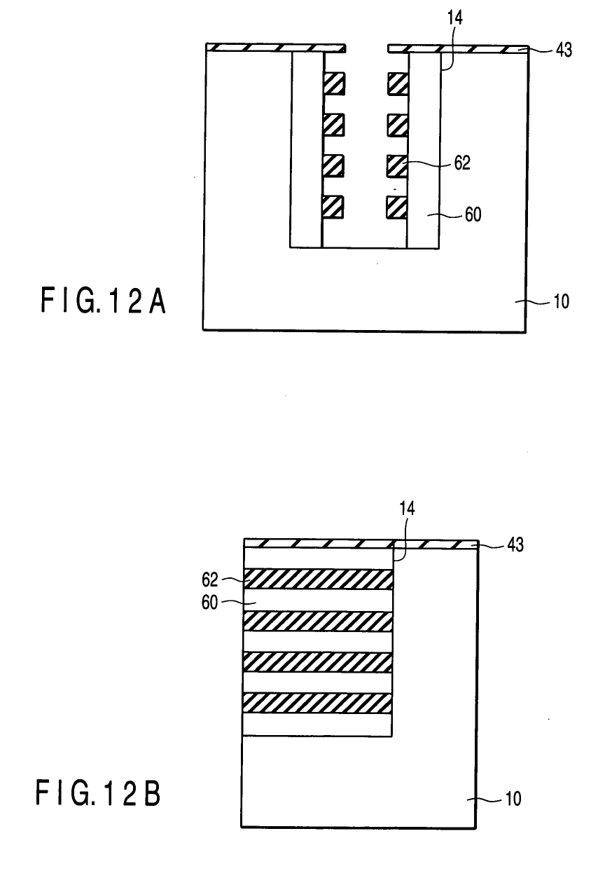

(9) Next, as shown in FIGS. 11A, 11B, a bit line contact 58 is being formed. FIG. 11A is a sectional view of the trench 14 vertical to the longitudinal direction, and FIG. 11B is a sectional view parallel to the surface of the silicon substrate 10 cut near the depth center of the trench 14 along the cutting line 11B-11B of FIG. 11A.

A tenth insulator (burying insulator) 56, e.g., CVD-SiO₂ film, is deposited over an entire surface including the inside of the trench 52 formed by removing the silicide metal 54m, filling the trench 52. Subsequently, the tenth insulator 56 deposited on the surface of the silicon substrate 10 is made thin and planarized by, e.g., CMP, while a part thereof is left.

Next, bit line contact holes 58h-1, 58h-2 are formed by lithography and etching in the tenth insulator 56 on the bottom electrode 38 in the width center of the trench 14 and on the source/drain 46 of the surface. Then, the contact holes 58h are filled with high-melting point metals such as tungsten (W) to form bit line contact plugs 58-1, 58-2.

Accordingly, a NAND type memory cell array 150 in which the memory cells 160 are two-dimensionally arranged on the side face of the trench 14 can be formed.

Subsequently, processes necessary for a semiconductor device, e.g., forming elements in peripheral circuits, multilevel wiring, and the like are carried out to complete a semiconductor device which includes the three-dimensional NAND type memory cell array 150.

As described above, the semiconductor device with three-dimensional structure of the present invention can comprise wirings and functional elements large enough to suppress fine-line effects. The wirings and functional elements are formed on the side face of the trench 14 formed vertically to the surface of the silicon substrate 10 irrespective of feature sizes of the functional elements formed on the surface of the silicon substrate 10.

Therefore, according to the present invention, it can be provided a three-dimensional semiconductor device capable of suppressing a performance reduction caused by fine-line effects even when the semiconductor device is miniaturized, and suited to high integration, and its manufacturing method.

### Second Embodiment

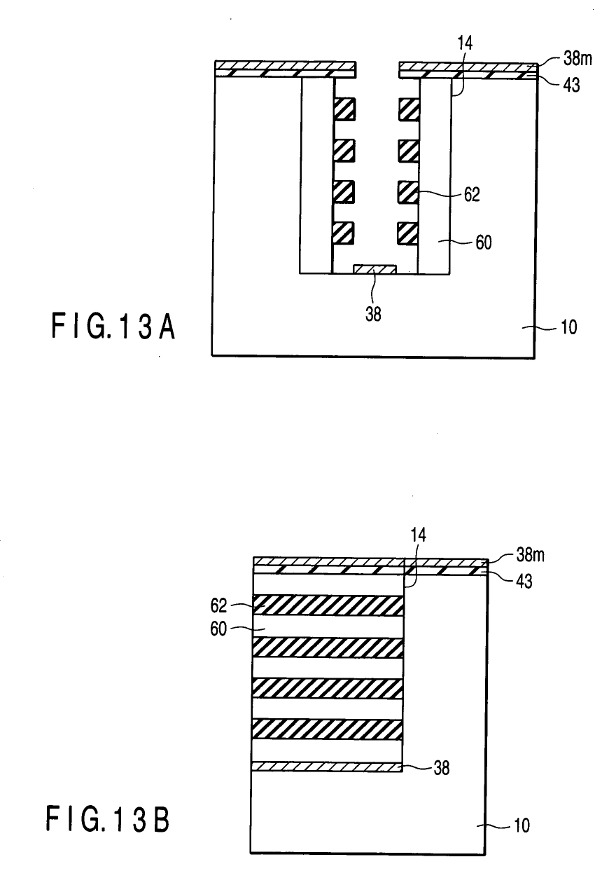

A second embodiment is a method of processing a side face of a concave portion, such as a trench, in a direction parallel to a bottom face. The embodiment will be described by taking an example in which a trench is formed in a semiconductor substrate or a semiconductor layer and a side face of the trench is processed in a direction parallel to the bottom face, as in the case of the step (6) of the first embodiment. However, the embodiment is not limited to this example. By way of example, a manufacturing process of the embodiment will be described RIE etching with reference to FIGS. 12A, 12B to FIGS. 17A, 17B, and 17C.

(1) FIG. 12A is a sectional view of the trench 14 vertical to a longitudinal direction showing a film 60 to be processed and a mask insulator 62 are formed on the side face of the trench 14 formed in the silicon substrate 10 by a method, for example, similar to that of the aforementioned steps (5) and (6) of the first embodiment or the like. FIG. 12B is a sectional view of an end of the trench 14 in the longitudinal direction. The film 60 to be processed is, for example, a semiconductor film (Si film). For example, the mask insulator 62 is SiN film. A plurality of mask insulators 62 is formed in parallel to a bottom face of the trench 14 and extending in the longitudinal direction of the trench 14.

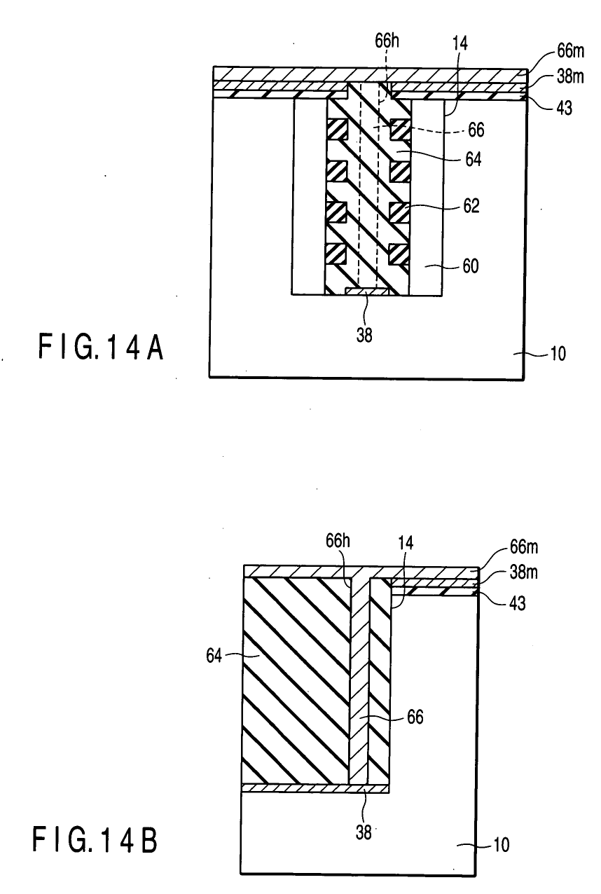

Prior to forming a bottom electrode 38 on the bottom face of the trench 14, a very thin insulator (not shown) is formed on the silicon substrate 10 to insulate the silicon substrate 10 and the bottom electrode 38. Then, as shown in FIGS. 13A, 13B, a bottom electrode material 38m, e.g., Ti, is deposited on the bottom surface of the trench 14 and a surface of the silicon substrate 10 by a method of selective deposition only on a horizontal surface, e.g., long throw sputtering. FIG. 13A is a sectional view of the trench 14 vertical to the longitudinal direction, and FIG. 13B is a sectional view of the end of the trench 14 in the longitudinal direction. As apparent from FIG. 13B, the bottom electrode 38 and the bottom electrode material 38m on the surface of the silicon substrate 10 are separated by the end of the trench 14 and thus not connected. Accordingly, to apply a bias to the bottom electrode 38, a wiring being formed outside of the trench 14 must be connected to the bottom electrode 38.

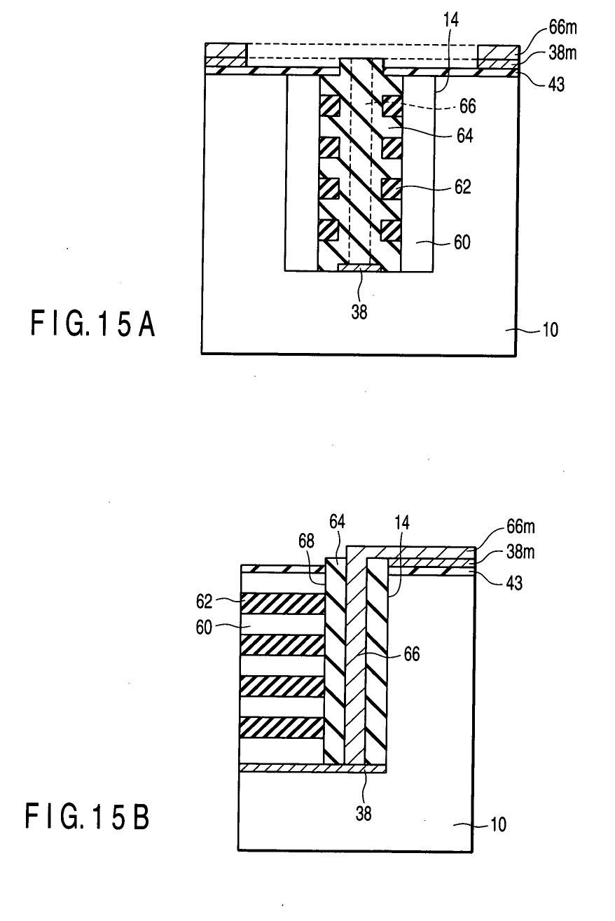

Therefore, as shown in FIGS. 14A, 14B, the inside of the trench 14 is filled with an insulator (burying insulator) 64 having a good step coverage and reflowing, e.g., boro-phospho silicate glass (BPSG). The burying insulator 64 formed on the surface of the silicon substrate 10 is removed by, e.g., CMP and etching back to expose the bottom electrode material 38m on the surface of the silicon substrate 10. FIG. 14A is a sectional view of the trench 14 vertical to the longitudinal direction, and FIG. 14B is a longitudinal sectional view of the end of the trench 14.

Further, as shown in FIGS. 14A, 14B, a contact hole 66h is formed in the burying insulator 64 by lithography and etching to reach the bottom electrode 38 near the end of the trench 14. A metal film 66b, e.g., Ti, is formed over an entire surface including inside of the contact hole 66h. Thus, as shown in FIG. 14B, a bottom electrode contact plug 66 can be formed being connected to the bottom electrode 38 in the end of the trench 14. Accordingly, the bottom electrode 38 is connected to the contact plug 66 and the metal film 66m above the surface of the silicon substrate 10. The metal film 66m is extending to a wafer edge.

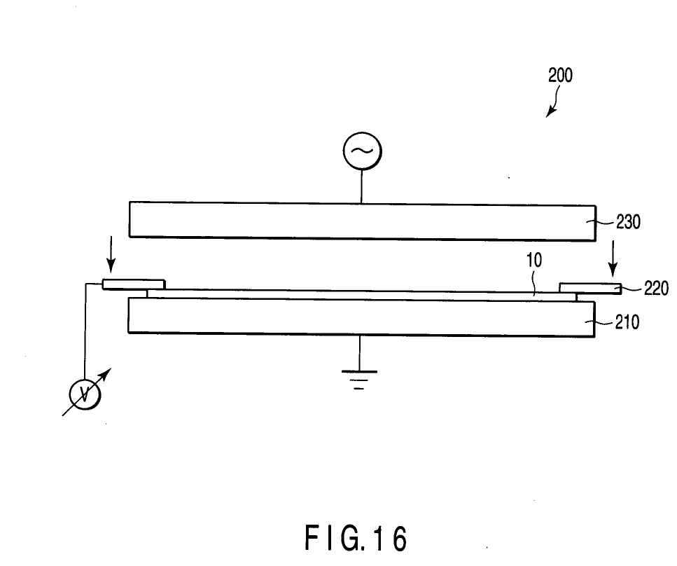

Next, as shown in FIGS. 15A, 15B, the metal film 66m and bottom electrode material 38m deposited on the surface around the trench 14, excluding the contact plug 66 portion, are removed by lithography and etching. FIG. 15A is a sectional view of the trench vertical to the longitudinal direction, and FIG. 15B is a longitudinal sectional view of the end of the trench 14.

Further, excluding a portion around the bottom electrode contact plug 66, the burying insulator 64 in the trench 14 is removed by lithography and etching to form a new trench 68. The trench 68 is formed to expose the bottom electrode 38 and the mask insulator 62 on the side face of the trench 14. Thus, a preparation is completed to process the target film 60 formed on the side face of the trench 14 in the lateral direction by using the bottom electrode 38.

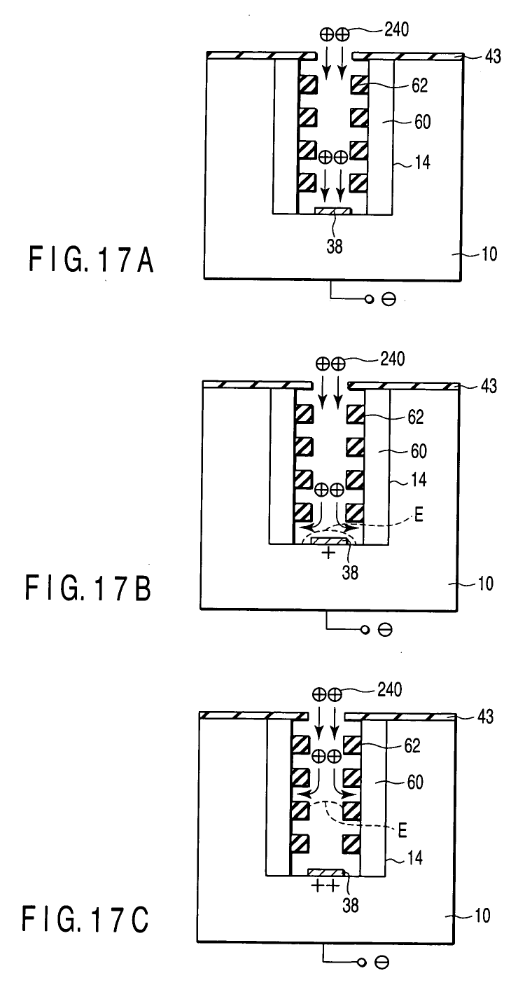

Next, the silicon substrate 10 is mounted on a processing device, e.g., a RIE device 200. FIG. 16 shows an example of the RIE device 200. The RIE device 200 comprises a stage 210 for mounting the silicon substrate 10, a clamp 220 for fixing the silicon substrate 10 from the surface side, and an upper electrode 230. The stage 210 and the clamp 220 are insulated, the stage 210 is grounded or applied a negative voltage to apply a negative substrate bias, and a positive voltage is applied to the clamp 220 to apply a positive potential to the bottom electrode 38. The voltage of the clamp 220 is preferably variable. A frequency of RIE processing is preferably 27 MHz or more to suppress so-called electron shading effect in which electrons are charged up near an inlet of the trench 14 to prevent reaching of an etchant 240 into the trench 14.

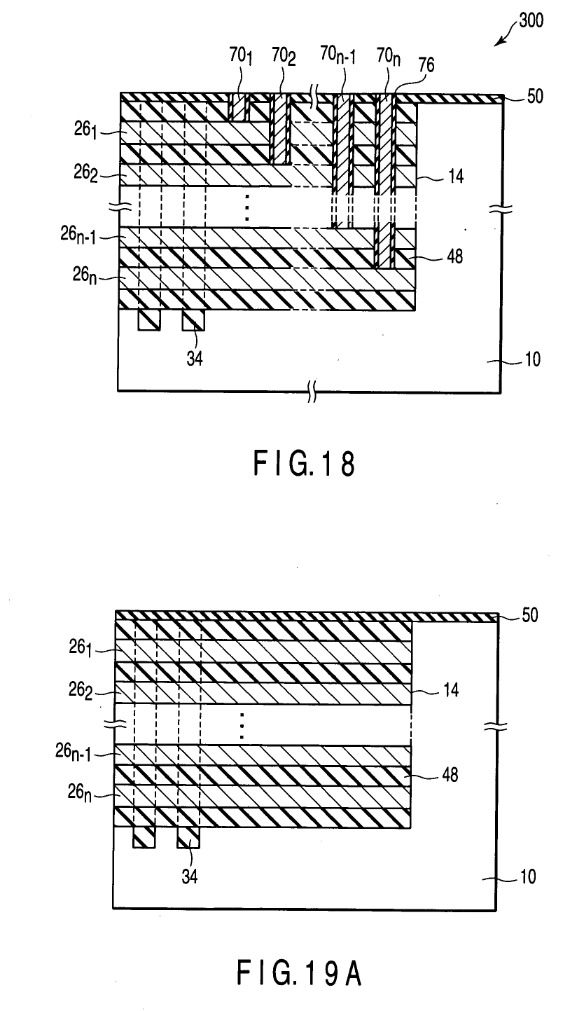

Next, lateral processing parallel to the bottom face of the trench 14 will be described with reference to FIGS. 17A to 17C.

The etchant 240 having positive charge is attracted by the negative substrate bias and enters the trench 14 vertically. If no bias is applied to the bottom electrode 38, as shown in FIG. 17A, then the etchant 240 moves directly to the bottom of the trench 14 to etch the bottom face (including bottom electrode 38) alone.

When a weak positive bias is applied to the bottom electrode 38, as shown in FIG. 17B, a positive etchant is repelled by an electric field E formed by the bottom electrode 38 near the same to lose its vertical velocity. Then, the etchant is attracted by the negative substrate bias of the side face of the trench 14 to move in the lateral direction to etch the side face of a deep part of the trench 14 from the lateral direction parallel to the bottom surface.

When the positive bias of the bottom electrode 38 is increased more, as shown in FIG. 17C, the electric field E formed by the bottom electrode 38 extends to an upper part of the trench 14. As a result, a position in which the positive etchant loses its vertical velocity is moved apart from the bottom electrode 38. Then, the positive etchant is attracted by the negative substrate bias of the side face of the trench of its depth to etch the side face of the trench 14 of a depth nearer the inlet of the trench 14 than that of FIG. 17B from the lateral direction.

Thus, by properly changing the positive bias applied to the bottom electrode 38, the side faces of the different depths in the trench 14 can be processed, e.g., etched, from the lateral direction parallel to the bottom face of the trench 14.

The lateral processing method of the embodiment to the direction parallel to the bottom face of the trench 14 is not limited to etching but can be applied to other processing which uses ionized species. For example, by substituting the etchant used here with a dopant having positive charges, the side face of the trench 14 can be doped from the lateral direction.

By reversing a polarity of a bias applied to the bottom electrode 38 and the substrate 10, a processing can be carried out by ionized species having a negative charge.

Furthermore, the embodiment is not limited to the trench formed in the substrate but can be applied to a case in which a trench-like concave is formed vertically in a semiconductor layer formed on the substrate. In this case, a side face of the trench-like concave portion is processed in a direction parallel to its bottom surface. The trench-like concave portion is not limited in the vertical direction to the substrate but may be formed in any optional direction such as a horizontal direction, and a side face of the concave portion can be processed in a direction parallel to its bottom face according to the embodiment.

### Third Embodiment

A third embodiment is directed to a structure of a contact connected to a plurality of wirings formed on a side face a trench and arranged in a vertical direction to be parallel to a bottom face of the trench 14 as in the case of the CG's 26 of the first embodiment, i.e., word lines 26, and its manufacturing method.

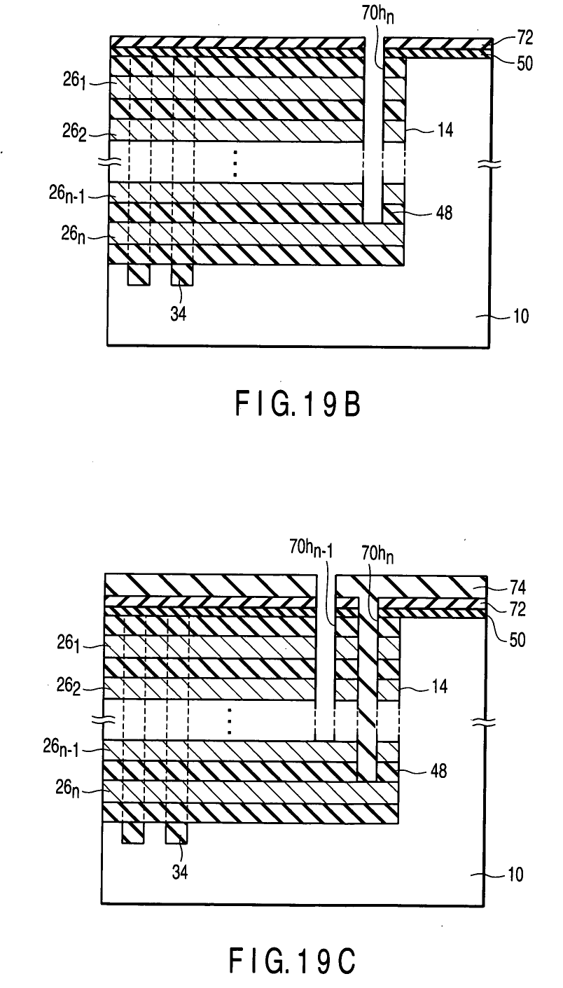

FIG. 18 is a diagram showing a structure of a three-dimensional wiring contact 300 which is an example of the embodiment. FIG. 18 shows a side face of the trench 14 near an end thereof. According to the embodiment, a plurality of contact plugs 70ₙ to 70₁ are formed to connect corresponding wirings 26ₙ to 26₁. Positions of the wiring contact plugs 70₁ to 70ₙ on a surface are changed with respect to depths of the corresponding wirings 26₁ to 26ₙ. A contact plug 70ₙ correspond to the deepest wiring 26ₙ is positioned closest to an end of the trench, and the larger a distance between the contact plug 70 and the end of the trench, the shallower the wiring 26 becomes. In the figure, in positions on the left of STI 34, functional elements, e.g., memory cells, are two-dimensionally arrayed on the side face of the trench 14. Each of wirings 26 is insulated by an interwiring insulator 48. An inner surface of each wiring contact hole 70h is covered with an insulator 76 to insulate the wiring 26 and the wiring contact plug 70 which intersect each other.

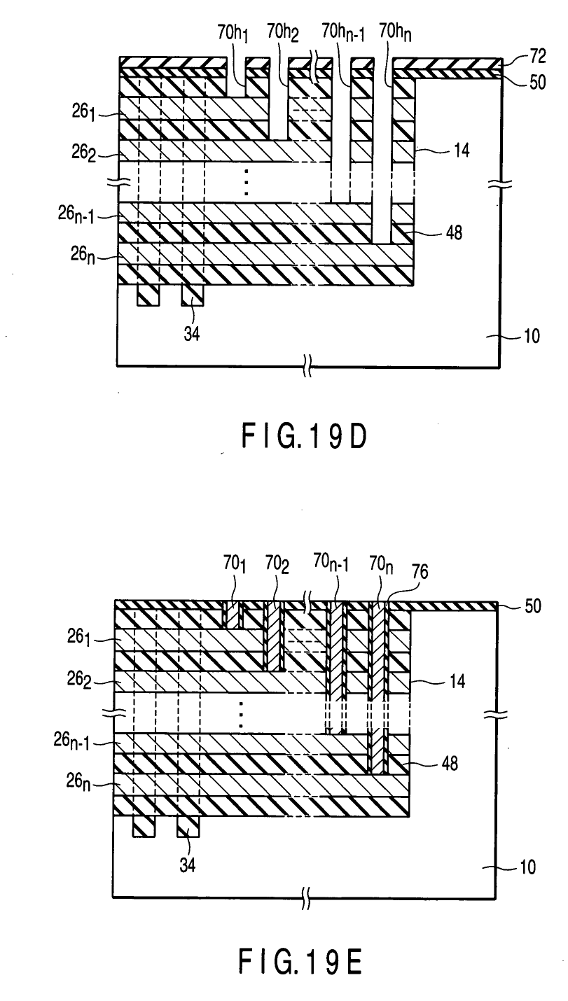

An example of a manufacturing method of the present invention will be described with reference to FIGS. 19A to 19E.

FIG. 19A shows a wiring 26 on a side face of a trench 14 of an end thereof after a memory cell and a bit line contact are formed in the trench 14 as in the case of after the step (9) of the first embodiment. However, the bit line contact is not shown. On the side face of the trench 14, a plurality of wirings 26₁ to 26ₙ are arranged in a vertical direction parallel to a bottom face of the trench 14. Moreover, a surface of a silicon substrate 10 is planarized and covered with a protective insulator 50.

Wiring contact plugs 70₁ to 70ₙ are formed with respect to wirings 26₁ to 26ₙ by lithography and etching. The wirings 26 are formed within the same plane of an equal distance from the side surface of the trench 14. Therefore, the wiring contact plugs 70 are formed by changing their positions in a longitudinal direction of the wirings 26.

First, as shown in FIG. 19B, a mask insulator 72, e.g., SiN film, is formed on an entire surface of the protective insulator 50. In the mask insulator 72 at a position close to the end of the trench 14, a pattern of a wiring contact hole 70hₙ corresponding to the deepest wiring 26ₙ is formed by lithography and etching. By using the mask insulator 72 as a mask, a wiring contact hole 70hₙ is formed by etching, e.g., RIE, to reach the wiring 26ₙ and intersect the wirings 26₁ to 26ₙ₋₁ disposed above the wiring 26ₙ.

Next, as shown in FIG. 19C, a resist 74 is formed on an entire surface including the inside of the contact hole 70hₙ, and a pattern of the contact hole 70hₙ₋₁ is formed in the resist 74 and the mask insulator 72 adjacent to the contact hole 70hₙ inner side of the trench 14. By using the resist 74 and the mask insulator 72 as masks, a wiring contact hole 70hₙ₋₁ is formed to reach a second deepest wiring 26ₙ₋₁. The wiring contact hole 70hₙ₋₁ is shallower than the previously formed wiring contact hole 70hₙ.

By repeating the processing above, as shown in FIG. 19D, wiring contact holes 70h₁ to 70hₙ with different depths are formed to reach respective wirings 26₁ to 26ₙ.

Next, as shown in FIG. 19E, a thin insulator 76, e.g., a CVD-SiO₂ film, is formed to cover an entire surface including the inside of each contact holes 70h.The insulator 76 insulates the wiring contact plug 70 which reaches the wiring 26 of a deeper position from the wiring 26 of a shallower position which intersects the plug. Subsequently, the insulator 76 on a bottom face of the contact hole 70h is removed by, e.g., RIE, to expose the wiring 26 to be connected.

Then, a contact plug material, e.g., phosphorus-doped polysilicon, tungsten (W), is deposited over an entire surface including the inside of each contact holes 70h. Then, the surface is planarized by, e.g., CMP, and the mask insulator 72 is removed, thereby completing wiring contact plugs 70₁ to 70ₙ connected to the wirings 26₁ to 26ₙ, respectively.

Accordingly, as shown in FIG. 18, a three-dimensional wiring contact 300 can be formed with respect to a plurality of wirings different in depth formed within the same vertical plane.

According to the wiring contact structure of the embodiment, when highly integrated two-dimensional memory cells are formed on the substrate surface, even if a feature size of 20 nm or less is required in which fine-line effects occur to cause a sudden increase in wiring resistance due to miniaturization of the device, the wirings and the contact plugs are three-dimensionally formed, and thus it can be set a feature size which can suppress the fine-line effects.

As described above, the present invention provides the semiconductor device of the three-dimensional structure in which by two-dimensionally arranging the functional elements such as NAND type memory cells on the side face of the trench, the performance degradation caused by the fine-line effects is suppressed even when the semiconductor device is miniaturized, and its manufacturing method. According to the present invention, irrespective of feature size of the functional element formed on the surface of the semiconductor substrate, a feature size of the functional element formed on the side face of the trench can be made sufficiently large. Thus, in the case of realizing high integration by miniaturization, it can be suppressed a performance degradation caused by the fine-line effects which is a problem in the conventional semiconductor device two-dimensionally arranged in plane.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor device comprising:
a semiconductor substrate including a trench vertically formed to a surface of the semiconductor substrate;
a plurality of isolations formed in side and bottom surfaces of the trench in a depth direction of the trench;
a plurality of functional elements formed on the side surfaces of the trench separated be the isolation and including an insulator, an electrode formed on the insulator and a pair of source/drain formed in the both sides of the electrode in the depth direction; and
a wiring connected to the electrodes located in both sides of the isolation.

2. The semiconductor device according to claim 1, further comprising a second electrode formed on the bottom face of the trench and connected to the source/drain and a contact connected to the second electrode, the contact extending outside of the trench from the bottom of the trench.

3. A semiconductor device comprising:
a semiconductor substrate including a trench vertically formed to a surface of the semiconductor substrate;
a plurality of isolations formed in an inner face of the trench in a vertical direction to the surface of the semiconductor substrate so as to separate the inner surface, separated inner surfaces separated by the isolations including an inner side surface and an inner bottom surface, respectively;
a plurality of memory elements formed on the inner side surface, including at least two gate insulators formed in the vertical direction, a plurality of source/drain formed in both sides of each gate insulator in the vertical direction and floating gate electrodes formed on the gate insulators and interelectrode insulators formed on the floating gate electrodes; and
at least two control gates electrode connecting the floating gate electrodes which adjoined in the both sides of the isolation.

4. The semiconductor device according to claim 3, wherein the control gate includes a silicide.

5. The semiconductor device according to claim 3, wherein the inner side surface of the trench is a (100) surface.

6. The semiconductor device according to claim 3, further comprising:
a plurality of contact plugs arranged in ends of the control gates, connected with the control gates, and formed to prevent intersection between the control gates.

7. A method of manufacturing a semiconductor device, comprising:
forming a first trench in a semiconductor layer vertically to a surface of the semiconductor layer;
forming a first insulator on an inner surface of the first trench;
forming a first silicon film on the first insulator;
forming isolations in the first insulator, the first silicon film, and the semiconductor layer in side and bottom faces of the first trench in a depth direction thereof;
forming a second insulator on surfaces of the first silicon film and the isolation;
forming a second silicon film on the second insulator;
removing the first and second insulators and the first and second silicon films formed on a bottom of the first trench;
forming an alternate stacked film of third and fourth insulators in the first trench to be parallel to the bottom face thereof;
forming a second trench in a center of the alternate stacked film;
forming an electrode in a bottom face of the second trench;
removing the third insulator;
patterning the second silicon film, the second insulator, the first silicon film, and the first insulator by using the fourth insulator as a mask while applying a potential to the electrode; and
introducing conductive impurities into the semiconductor layer while applying the potential to the electrode.

8. The method according to claim 7, wherein the patterning is executed by applying a potential to the electrode with an opposite polarity to that of the semiconductor layer, and the introducing the impurities is executed by applying a potential to the electrode with an opposite polarity to that of the semiconductor layer.

9. The method according to claim 7, wherein the potential applied to the electrode is variable.

10. The method according to claim 7, wherein the electrode contains a silicide.

11. The method according to claim 7, further comprising:
removing a part or all of the electrode.
